(19) United States
(12) Patent Application Publication
(10) Pub. No.: US 2009/0056984 A1
(43) Pub. Date: Mar. 5, 2009

(54) SIGNAL TRANSMISSION STRUCTURE AND LAYOUT METHOD FOR THE SAME

(75) Inventors: Shih-Chieh Chao, Taipei (TW); Chih-Wen Huang, Taipei (TW); Chun-Lin Liao, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: TATUNG COMPANY, Taipei (TW)

(21) Appl. No.: 11/951,345

(22) Filed: Dec. 6, 2007

(30) Foreign Application Priority Data
Sep. 5, 2007 (TW) 96133057

(51) Int. Cl. H05K 1/02

(52) U.S. Cl. 174/255

(57) ABSTRACT

A signal transmission structure is provided. The signal transmission structure includes conduction blocks periodically formed at a power plane, neck blocks connecting adjacent conduction blocks, and openings formed corresponding to the neck blocks at a ground plane for reducing equivalent capacitance between the neck blocks and the ground plane, so as to improve the noise isolation performance.

### CROSS-REFERENCE TO RELATED APPLICATION

This application claims the priority benefit of Taiwan application serial no. 96133057, filed on Sep. 5, 2007. The entirety of the above-mentioned patent application is hereby incorporated by reference herein and made a part of this specification.

### BACKGROUND OF THE INVENTION

1. Field of the Invention

The present invention generally relates to a signal transmission structure, and more particularly, to a signal transmission structure of a power plane and a ground plane, and a layout method for the signal transmission structure.

2. Description of Related Art

In order to prevent propagation of electromagnetic noise in a printed circuit board (PCB), decoupling capacitors are often provided to filter the electromagnetic noise. However, because of the equivalent series inductance of the capacitors, the effective noise filtering bands for decoupling capacitors are usually below 500 MHz.

In higher frequency bands, for example a frequency band higher than 1 GHz, an effective method for the noise isolation is using a layout method to form slots or openings at power and/or ground planes. Two structures provided for the layout method are known as an embedded structure and a single metal cutting structure respectively. FIG. 1 is a schematic structural diagram illustrating a conventional embedded structure. As shown in FIG. 1, a layer of metal blocks 111 which are periodically grounded are embedded between a power plane 110 and a ground plane 120 for forming a high impedance structure for surface waves, and thus suppressing the propagation of electromagnetic noise. The embedded metal blocks 111 are periodically formed between the power plane 110 and the ground plane 120, and are connected to the ground plane 120 through vias 121. This structure has an advantage that upper and bottom metal layers thereof can be formed complete power plane (without cutting), and thus it can provide continuous return current paths for adjacent signal line layer. However, this structure still has a disadvantage in that three metal layers are required, and the vias 121 are further required to configure in the PCB for connecting the embedded metal blocks 111 and the bottom metal layer, i.e., the ground plane 120, both of which increase production costs thereof.

FIG. 2 is a schematic structural diagram illustrating a conventional single layer metal cutting structure. As shown in FIG. 2, this structure is formed by directly etching a metal layer which constitutes a power plane 210. The metal cutting layer is divided into periodically formed blocks. Adjacent blocks are connected with short metal necks 211 for keeping the blocks at an equal potential. Comparing with the embedded structure as shown in FIG. 1, the single layer metal cutting structure requires less metal layers and does not require vias, and thus requires lower production cost. However, the performance of the single layer metal cutting structure shown in FIG. 2 is not as good as that of structure shown in FIG. 1.

For further improving the noise filtering performance, another approach has been proposed, in which the metal necks 211 are prolonged to increase the inductances, as shown in FIG. 2. Unfortunately, this makes the power plane metal layer too complicated so as to cause discontinuity in return current path of adjacent signal line layer.

### SUMMARY OF THE INVENTION

Accordingly, the present invention is directed to a signal transmission structure. The signal transmission structure includes conduction blocks periodically formed at a power plane, neck blocks connecting adjacent conduction blocks, and openings formed corresponding to the neck blocks at a ground plane for reducing equivalent capacitance between the neck blocks and the ground plane. The signal transmission structure improves the performance of isolating electromagnetic noise by increasing a characteristic impedance of the neck blocks.

The present invention is also directed to a layout method for a signal transmission structure. The layout method includes providing a patterned layout to obtain the aforementioned signal transmission structure for improving the noise filtering performance of the power plane and suppressing the noise propagation capability.

The present invention is also directed to a signal transmission structure. The signal transmission structure includes a plurality of conduction blocks, at least one neck block, and at least one opening. The conduction blocks are periodically formed at a first reference plane. At least one neck block is formed between adjacent conduction blocks for electrically connecting the adjacent conduction blocks. At least one opening is formed at a second reference plane at a position corresponding to the neck block. The first reference plane and the second reference plane are adjacent one to another.

According to an embodiment of the present invention, the opening has identical shape and size of the neck block.

According to an embodiment of the present invention, the first reference plane is a power plane, and the second reference plane is a ground plane.

According to an embodiment of the present invention, the signal transmission structure further includes a dielectric layer formed between the first reference plane and the second reference plane.

According to an embodiment of the present invention, the first plane and the second plane are composed of metal layers.

According to an embodiment of the present invention, the conduction blocks are rectangular or orthohexagonal.

According to another aspect, the present invention provides a layout method for a signal transmission structure including the steps of: periodically forming a plurality of conduction blocks at a first reference plane; forming at least one neck block to connect adjacent conduction blocks; and forming at least one opening at a second reference plane at a position corresponding to the at least one neck block, in which the first reference plane and the second reference plane are adjacent one to another.

The present invention correspondingly disposes openings at the ground plane to reduce the equivalent capacitance between the ground plane and the power plane to further increase the characteristic impedance of the neck block. In such a way, the electromagnetic transmission between adjacent conduction blocks is lowered, and the noise isolation performance can be improved accordingly. Further, the neck blocks need not be thin and long, and therefore the layout of the power plane can be simplified to improve signal quality. Meanwhile, the corresponding opening need not be too large so that the metal layer of the ground plane is substantially complete. As such, the signal transmission structure according to the present invention is adapted to improve the signal quality and noise isolation performance when working at a high frequency.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic structural diagram illustrating a conventional embedded structure.

FIG. 2 is a schematic structural diagram illustrating a conventional single layer metal cutting structure.

FIG. 3 is a schematic diagram illustrating a signal transmission structure according to a first embodiment of the present invention.

FIG. 4 is a cross-sectional view of a neck block according to the first embodiment of the present invention.

FIG. 5A is a schematic structural diagram illustrating a first reference plane according to the first embodiment of the present invention.

FIG. 5B is a schematic structural diagram illustrating a second reference plane according to the first embodiment of the present invention.

FIG. 6 is a schematic diagram illustrating a signal transmission structure according to a second embodiment of the present invention.

FIG. 7A is a schematic structural diagram illustrating a first reference plane according to the second embodiment of the present invention.

FIG. 7B is a schematic structural diagram illustrating a second reference plane according to the second embodiment of the present invention.

FIG. 8A shows curves simulating transmission coefficients of respectively an original power plane and the first embodiment of the present invention.

FIG. 8B is a schematic diagram of simulation ports in accordance with the original power plane.

FIG. 8C is a schematic diagram of simulation ports in accordance with the first embodiment.

FIG. 9 is a flow chart illustrating a layout method according to a third embodiment of the present invention.

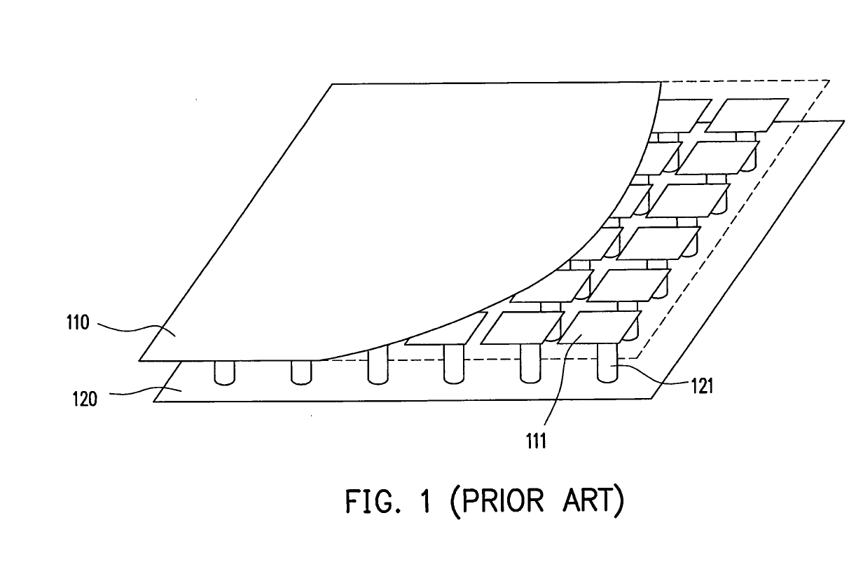

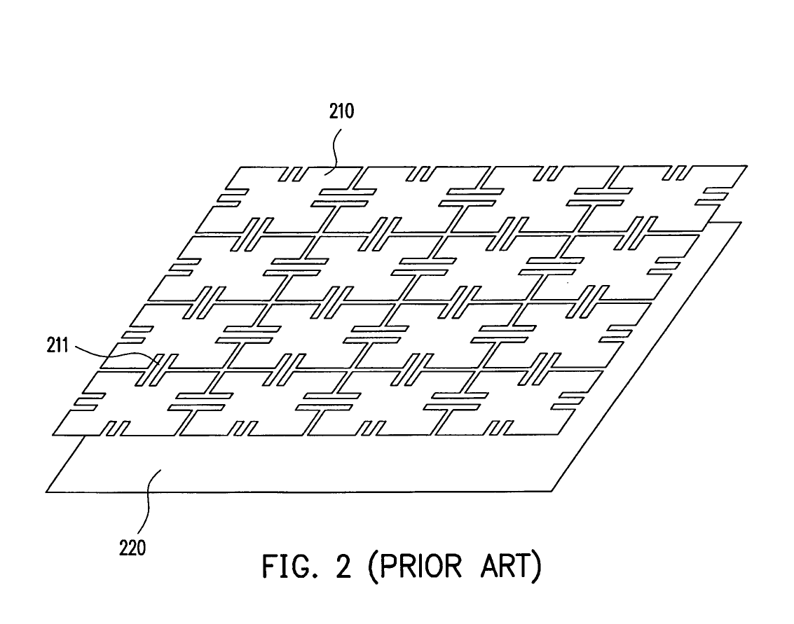

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

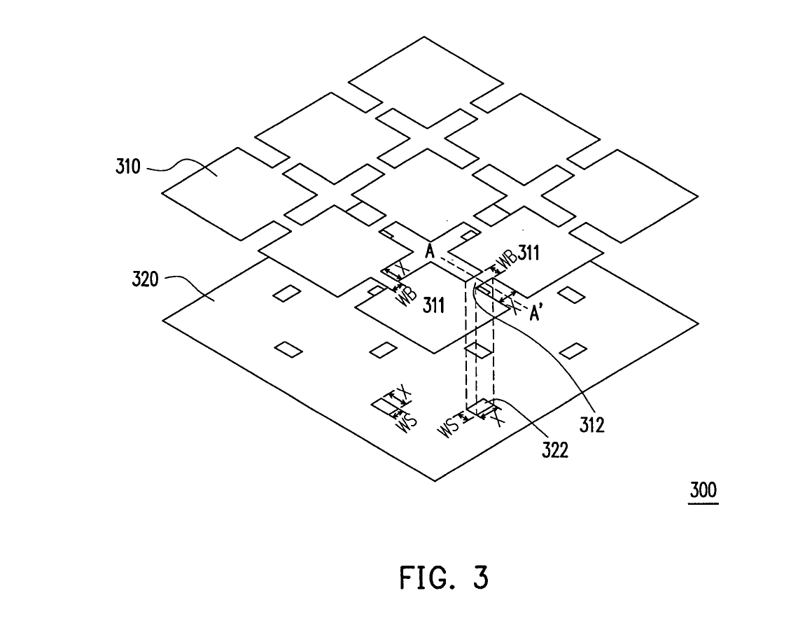

FIG. 3 is a schematic diagram illustrating a signal transmission structure according to a first embodiment of the present invention. Referring to FIG. 3, there is shown a signal transmission structure 300. The signal transmission structure 300 includes a first reference plane 310 and a second reference plane 320. According to an aspect of the first embodiment, the first reference plane 310, for example, is a power plane, and the second reference plane 320, for example, is a ground plane.

The first reference plane 310 is composed of a plurality of conduction blocks 311. A connecting channel connecting adjacent conduction blocks 311 is defined as a neck block 312. The first reference plane 310 is composed of periodically formed conduction blocks 311 and neck blocks 312. The second reference plane 320 and the first reference plane 310 are adjacent one to another, such as adjacent upper and bottom surfaces or different metal layers of a PCB. The second reference plane 320 has at least one opening 322. The opening 322 is formed at a position corresponding to the neck block 312 of the first reference plane 310, i.e., the opening 322 is formed at a where the neck block 312 is positively projected on the second reference plane 320. In other words, when viewing from the top, the opening 322 overlaps the corresponding neck block 312. In this embodiment, shape and size of the opening 322 is not to be restricted. According to an aspect of the embodiment, the shape and the size of the opening 322 are equivalent with that of the neck block 312.

It is noted that when the opening 322 is slightly larger than the neck block 312, the first reference plane 310 achieves a better noise isolation performance, while the completeness of the second reference plane 320 is affected. When the opening 322 is slightly smaller than the neck block 312, the second reference plane 320 achieves a better completeness, while the noise isolation performance of the first reference plane 310 is affected. As such, those skilled in the art would understand to vary or modify the above embodiment of the present invention in designing the shape and size of the opening 322, according to the requirement and demand of products to be complied with. However, regardless of the opening 322 whether it is larger than, equivalent to, or smaller than the neck block 312, the noise isolation performance of the current embodiment is always better compared to that of the conventional art. For better illustration and simplification, the current embodiment is exemplified in a condition that the opening 322 and the neck block 312 are exactly same in shape and size, as below.

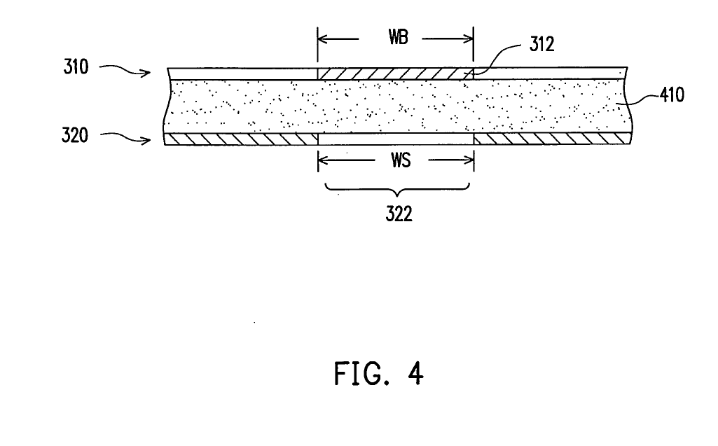

FIG. 4 is a cross-sectional view of the neck block 312 along line A-A′ as shown in FIG. 3, according to the first embodiment of the present invention. Referring to FIG. 4, the neck block 312 is formed at an upper side of the second reference plane 320. The opening 322 is formed at a position corresponding to the neck block 312. According to the present embodiment, positions of respectively the opening 322 and the neck block 312 overlap one to another. In other words, the opening 322 is equivalent as a hole etched from the second reference plane 320 at a position corresponding to the neck block 312 so as to reduce an equivalent capacitance between the neck block 312 and the second reference plane 320. A reduced equivalent capacitance between the neck block 312 and the second reference plane 320 allows the neck block 312 to obtain a higher characteristic impedance, so as to improve the electromagnetic noise isolation performance. The neck block 312 may vary to have different structures. While the principle of operation remains the same, the variations are not to be iterated hereby.

In the present embodiment, the opening 322 and the neck block 312 are identical in shape and size. Therefore, the neck block 312 at the first reference plane 310 has a width WB is equal to a width of the opening 322 at the second reference plane 320. The neck block 312 and the opening 322 have an equivalent length X, as shown in FIGS. 3 and 4. As such, in the signal transmission structure 300 of FIG. 3, the neck block 312 and the opening 322 not only overlaps one to another, but also have a same shape and size. However, it should be noted that in any of the embodiment illustrated or to be illustrated according to the present invention, the size of the opening is not restricted by the width WB of the neck block. Although the neck block and the opening are required to be formed at corresponding positions, the size of the opening can be modified or adjusted as practically needed. Whenever there is an opening formed corresponding to a neck block according to the present invention, the capacitance thereof will be drastically decreased. It has been found that simulation, when the neck block and the corresponding opening have same shape and size, the noise isolation performance of the signal transmission structure and the structure completeness thereof are relatively good, considering in their entireties.

In the first embodiment of the present invention, because the neck block 312 has an area smaller than that of the conduction block 311, and in further consideration of the effect of the opening 322, the equivalent capacitance between the neck block 312 and the second reference plane 320 is relatively small and an equivalent inductance of the neck block 312 is relatively large. As such, the neck block 312 has a relatively large characteristic impedance, and thus is capable of suppressing the electromagnetic noise propagation. Adjacent conduction blocks 311 achieve a same direct current potential by the neck block 312. Taking advantage of the characteristic impedance of the neck block 312, the signal transmission structure 300 can achieve a better noise isolation performance.

When the first reference plane 310 is taken as a power plane, because of the high characteristic impedance caused by the neck block 312, the electromagnetic noise is also isolated in individual conduction blocks 311. As periodically designed, a layout can improve the noise isolation performance at a high frequency band. The more the conduction blocks 311 and the neck blocks 312, the better the noise isolation performance of the transmission structure.

The signal transmission structure 300 can be directly applied to a printed circuit board (PCB). As shown in FIG. 4, the first reference plane 310 is a power plane, and the second reference plane 320 is a ground plane. The signal transmission structure further includes a dielectric layer 410 between the first reference plane 310 and the second reference plane 320 for isolating these two reference planes 310, 320 one from another. The first reference plane 310 and the second reference plane 320 are usually made of metal layers. As such, the signal transmission structure 300 according to the foregoing embodiments of the present invention can be fabricated with a layout by PCB processing.

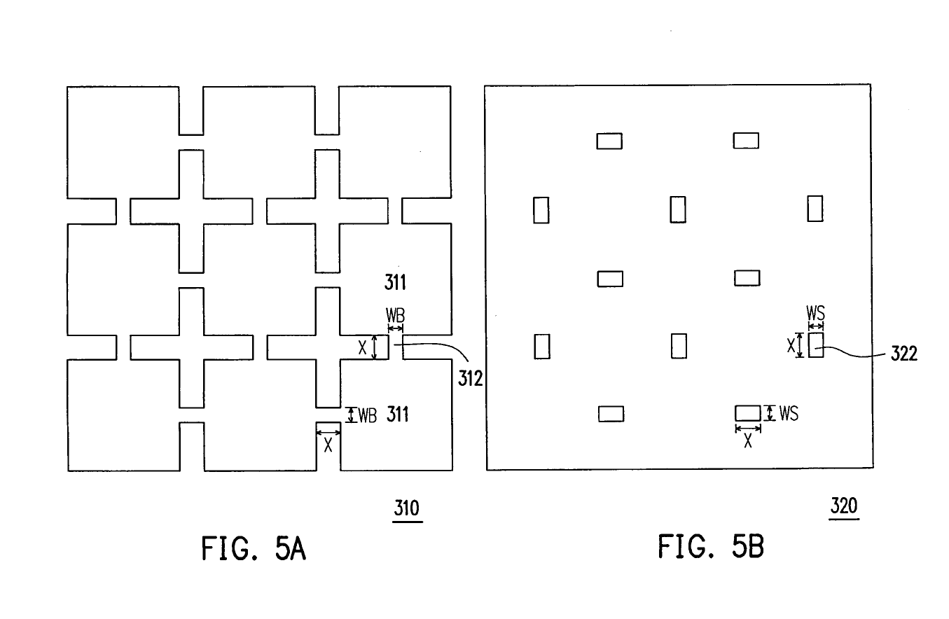

For clearer illustration of the present invention, a layout structure of the first reference plane 310 and the second reference plane 320 are shown respectively in FIGS. 5A and 5B. FIG. 5A is a schematic structural diagram illustrating the first reference plane 310 according to the first embodiment of the present invention, and FIG. 5B is a schematic structural diagram illustrating the second reference plane 320 according to the first embodiment of the present invention. Referring to FIG. 5A, the first reference plane 310 includes a plurality of conduction blocks 311 and a plurality of neck blocks 312. The neck blocks 312 are responsible of connecting adjacent conduction blocks 311. The neck blocks 312 are long, thin wires having a relatively high equivalent inductance which presents a relatively high characteristic impedance to noise at a high frequency band. Such neck blocks 312 achieve better noise isolation performance, while has no affection to transmission of direct current.

In order to further improve the noise isolation performance of the neck blocks 312, the present embodiment etches openings 322 as shown in FIG. 5B at positions at the second reference plane 320 corresponding to the neck blocks 312. The second reference plane 320 has a plurality of openings 322 formed thereat. Each of the openings 322 is positioned in correspondence with a neck block 312 at the first reference plane 310. Taking the openings 322 and the corresponding neck blocks 312 labeled in FIGS. 5A and 5B for example, the labeled openings 322 are adapted for decreasing equivalent capacitance between the labeled neck block 312 and the second reference plane 32Q, and thus improving the characteristic impedance of the neck blocks 312 at high frequency bands.

Furthermore, it should be noted that although the current embodiment illustrates the present invention as the conduction blocks and the neck blocks being of a rectangular shape, the layout of the conduction blocks and the neck blocks of the present invention is not to be restricted. Although the layout of the signal transmission structure of the current embodiment is shown as periodically repeated, e.g., 3*3 as shown in the drawings, the size of the matrix of the signal transmission structure is not to be restricted hereby. Those of ordinary skill in the art may modify the layout, sizes, and shapes of the conduction blocks and the neck blocks in accordance with the practical need. As discussed above, the configuration of openings corresponding to the neck blocks at the second reference plane is adapted for decreasing the equivalent capacitance between the neck block and the second reference plane, so as to increase the characteristic impedance of the neck blocks at the first reference plane, and thus improving the electromagnetic noise isolation performance.

### Second Embodiment

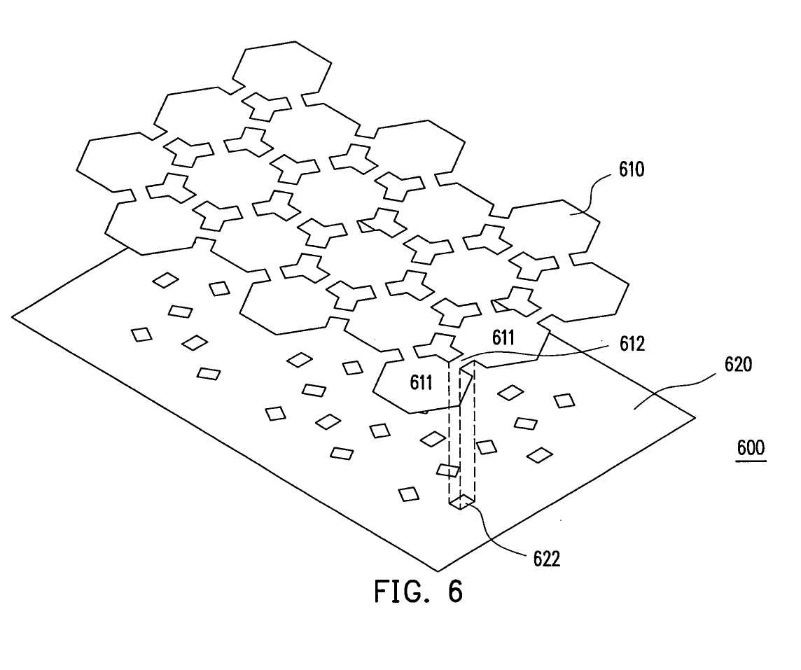

FIG. 6 is a schematic diagram illustrating a signal transmission structure according to a second embodiment of the present invention. Referring to FIG. 6, a signal transmission structure 600 includes a first reference plane 610, and a second reference plane 620. The first reference plane 610 for example is a power plane, and the second reference plane 620 for example is a ground plane.

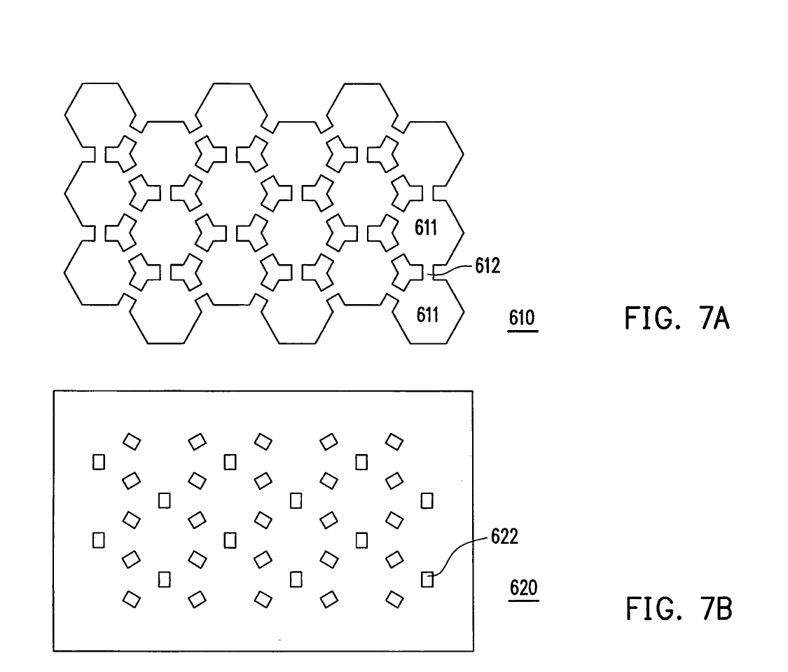

The first reference plane 610 is composed of a plurality of orthohexagonal conduction blocks 611 which are periodically formed. Adjacent conduction blocks 611 are connected by neck blocks 612. The second reference plane 620 includes a plurality of openings 622 formed at positions corresponding to the neck blocks 612 for decreasing an equivalent capacitance between the neck blocks 612 and the second reference plane 620. Now referring to FIGS. 7A and 7B, there are shown structural diagrams of respectively the first reference plane and the second reference plane and layouts thereof according to the second embodiment of the present invention as shown in FIG. 6. Referring to FIGS. 7A and 7B, the second reference plane 620 includes at least one opening 622 formed corresponding to the position of the neck block 612 so as to improve the electromagnetic noise isolation performance of the neck block 612. Details of the embodiment of FIGS. 7A and 7B can be learnt by referring to the first embodiment and the drawings associated therewith, and are not to be further iterated hereby.

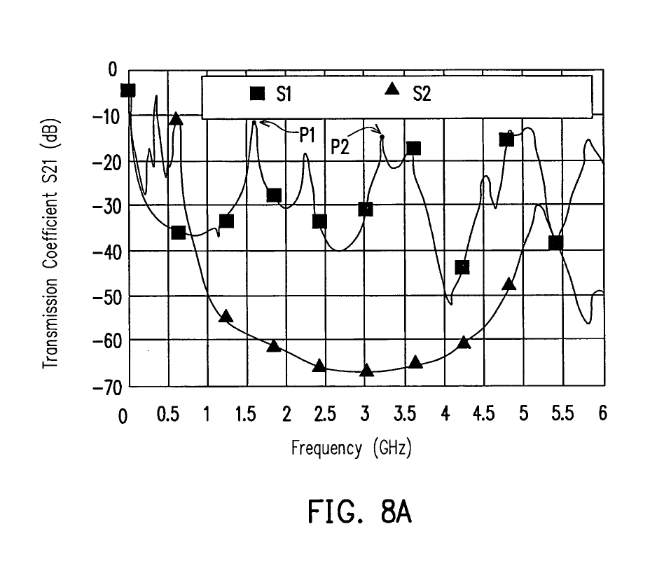

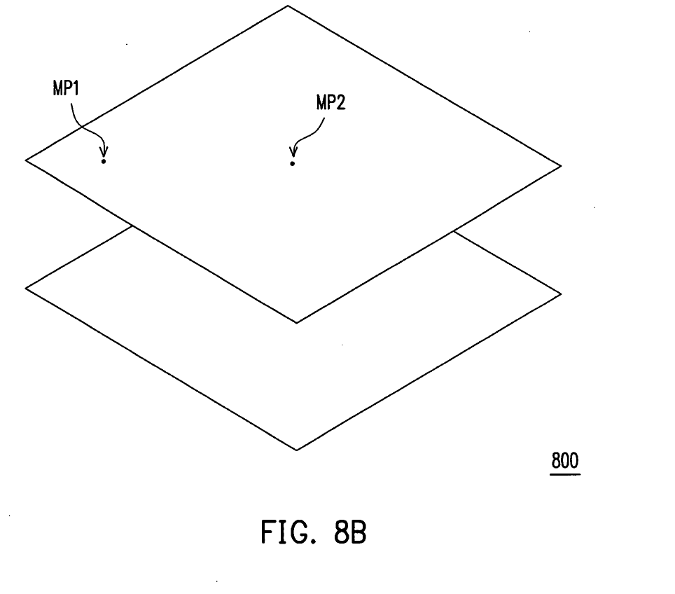

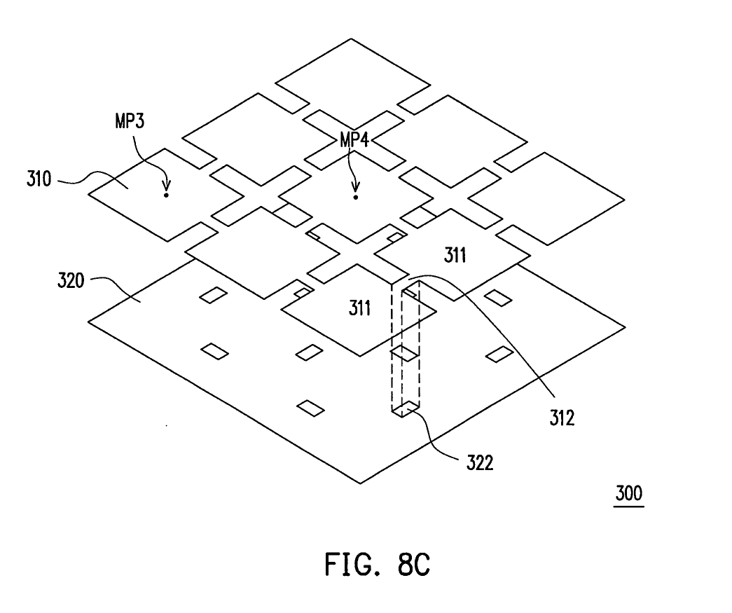

FIG. 8A shows curves simulating transmission coefficients of respectively an original power plane and the first embodiment of the present invention. FIG. 8B is a schematic diagram of simulation ports in accordance with the original power plane. FIG. 8C is a schematic diagram of simulation ports in accordance with the first embodiment. Referring to FIG. 8A, a curve S1 describes an original power plane 800, and shows the variations of a transmission coefficient S21 according to changes of frequency corresponding thereto before the original power plane 800 is etched; a curve S2 describes the first embodiment, and shows the variations of the transmission coefficient S21 according to changes of frequency corresponding thereto, in which the transmission coefficient S21 is either a forward transmission coefficient or a reverse transmission coefficient of a scattering parameter. Referring to FIGS. 8B, and 8C, there are shown simulation ports MP1, MP2 for the curve S1 and in FIG. 8B, and MP3, MP4 for the curve S2 in FIG. 8C. Simulation ports MP1, MP2 in FIG. 8B respectively correspond to simulation ports MP3 and MP4 in FIG. 8C. In other words, the simulation ports MP1, MP2 of the original power plane 800 are configured at identical positions of the simulation ports MP3, MP4 of the signal transmission structure 300 according to the first embodiment of the present invention.

Referring to FIG. 8A, and as shown in the curve S1, there are many peaks, e.g., P1, P2, of the transmission coefficient S21 between the simulation ports MP1 and MP2 of the original power plane 800 at a frequency band between 0 Hz to 6 GHz due to the resonant effect of the PCB. As shown in the curve S2, in a frequency band between 1 GHz and 5 GHz, the simulated transmission coefficients S21 between the simulation ports MP3 and MP4 of the signal transmission structure 300 of the first embodiment are all lower than −40 dB. Therefore, the noise isolation performance of the signal transmission structure 300 of the first embodiment is much better than that of the original power plane before being etched.

Moreover, the curve S2 describes variations of the transmission coefficients S21 with the simulation ports MP3 and MP4 arbitrarily selected from conduction blocks 311. When the layout of the conduction blocks 311 or the neck blocks 312, or the simulation ports are different, such as the second embodiment, the transmission coefficient S21 may also change. As such, FIG. 8A is only exemplified for comparing the original power plane and the first embodiment as a reference, and is not for further restricting the present invention.

### Third Embodiment

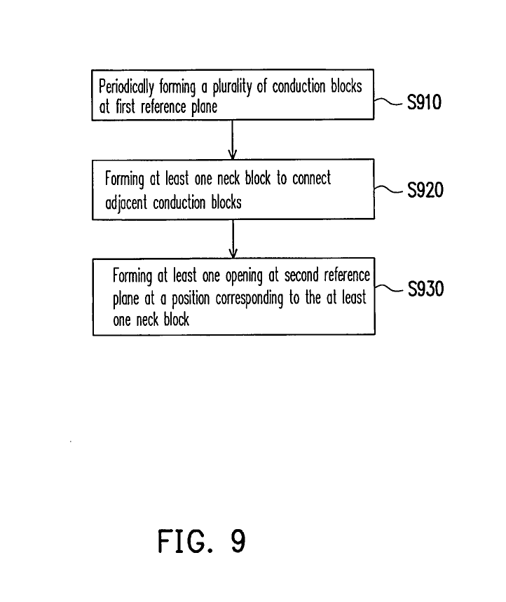

According to another aspect, the present invention provides a layout method for a signal transmission structure. As shown in FIG. 9, there is shown a flow chart of a layout method according to the third embodiment of the present invention. The layout method includes: periodically forming a plurality of conduction blocks at a first reference plane (step S910); forming at least one neck block to connect adjacent conduction blocks, wherein when there are only two conduction blocks formed at the first reference plane, and only one neck block needed for connecting the two conduction blocks (step S920); and forming at least one opening at a second reference plane at a position corresponding to the neck block, in which the first reference plane and the second reference plane are adjacent one to another (step S930).

In the step S930, the opening can be larger than, smaller than or equivalent to the neck block. The present invention can be applied to a PCB, in which the first reference plane can be a power plane, and the second reference plane can be a ground plane. Other details of the current embodiment can be learnt by referring to the description about the first and the second embodiments above. Those of ordinary skill in the art should have been well taught thereby about the details.

The signal transmission structure according to the present invention is not only adapted for PCBs, but also can be applied in other fields, such as semiconductor encapsulation substrate, low temperature co-fired ceramic (LTCC) substrate, all of which can obtain better electromagnetic noise isolation performance in compliance with the present invention. Further, the present invention includes at least the following advantages.
1. Better noise isolation performance can be achieved without introduction too complicated layout of the power plane and does not require too long neck blocks.
2. The openings of the ground plane are not required to be too large, and therefore adapted to keep the completeness of the ground plane, and won't affect the wiring of adjacent metal layers; and
3. Much better noise isolation performance can be achieved when working with decoupling capacitors.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A signal transmission structure, comprising:
a plurality of conduction blocks, periodically formed at a first reference plane;
at least one neck block, formed between adjacent conduction blocks for connecting the adjacent conduction blocks; and
at least one opening, formed at a second reference plane at a position corresponding to the neck block,
wherein the first reference plane is adjacent to the second reference plane.

2. The signal transmission structure according to claim 1, wherein the opening has a same shape and size of the neck block.

3. The signal transmission structure according to claim 1, wherein the first reference plane is a power plane.

4. The signal transmission structure according to claim 1, wherein the second reference plane is a ground plane.

5. The signal transmission structure according to claim 1 further comprising a dielectric layer formed between the first reference plane and the second reference plane.

6. The signal transmission structure according to claim 1, wherein the first reference plane and the second reference plane are composed of metal layers.

7. The signal transmission structure according to claim 1, wherein the conduction blocks are rectangular.

8. The signal transmission structure according to claim 1, wherein the conduction blocks are orthohexagonal.

9. A layout method for a signal transmission structure, comprising:
periodically forming a plurality of conduction blocks at a first reference plane;
forming at least one neck block to connect adjacent conduction blocks; and
forming at least one opening at a second reference plane at a position corresponding to the neck block, wherein the first reference plane is adjacent to the second reference plane.

10. The layout method according to claim 9, wherein the opening has a same shape and size of the neck block.

11. The layout method according to claim 9, wherein the first reference plane is a power plane.

12. The layout method according to claim 9, wherein the second reference plane is a ground plane.

13. The layout method according to claim 9 further comprising a dielectric layer formed between the first reference plane and the second reference plane.

14. The layout method according to claim 9, wherein the first reference plane and the second reference plane are composed of metal layers.

15. The layout method according to claim 9, wherein the conduction blocks are rectangular.

16. The layout method according to claim 9, wherein the conduction blocks are orthohexagonal.
